(19) United States
(12) Patent Application Publication
(10) Pub. No.: US 2002/0068407 A1
(43) Pub. Date: Jun. 6, 2002

(54) MOS transistor fabrication method

(76) Inventor: Atsuki Ono, Tokyo (JP)

Correspondence Address: ROSENMAN & COLIN LLP, 575 MADISON AVENUE, NEW YORK, NY, 10022-2585, US

(21) Appl. No.: 10/010,339

(22) Filed: Dec. 5, 2001

(30) Foreign Application Priority Data
Dec. 6, 2000 (JP) 372121/2000

(51) Int. Cl. H01L 21/336

(52) U.S. Cl. 438/279

(57) ABSTRACT

A MOS transistor fabrication method of the present invention comprises a step of forming a gate insulating film upon a semiconductor substrate; a step of forming a silicon film made from polysilicon or amorphous silicon upon the gate insulating film; a step of applying a heat treatment carried out at 800 to 1000° C. and for a duration of 1 to 10 seconds on the silicon film; a step of pre-doping by implanting impurity ions into the silicon film; a step of patterning a gate electrode by etching the silicon film; a step of forming sidewalls at the side portions of the gate electrode; and a step of doping the gate electrode with an impurity by implanting ions into the gate electrode and the semiconductor substrate as well as forming a source and a drain on the surface of the semiconductor substrate.

### BACKGROUND OF THE INVENTION

1. Field of the Invention

The present invention relates to a MOS transistor fabrication method including a pre-doping process. In particular, it relates to one that aims to reduce variations in form and electrical characteristics of a gate electrode.

2. Description of the Prior Art

Recently, in response to demands for improvements in the efficiency of MOS transistors, miniaturization of gate size and film thickness and the like of gate insulating films thereof have been progressing. In particular, it is the tendency for gate insulating films to be made thin to allow for higher efficiency. For example, in an MOS transistor with a 0.1 μm-long gate, a gate insulating film is configured by a silicon oxide film including nitrogen, with a thickness that has been made as low as approximately 2 nm. This is determined by the current when the transistor function is ON, or in other words, the ON-current, wherein the larger the ON-current obtained from a low gate voltage the higher the performance efficiency of the transistor. However, the ON-current flow is dependant on the amount of charge in an inversion layer formed between the gate insulating film and the channel region; and the amount of charge in the inversion layer is dependent on the film thickness of the gate insulating film. Therefore, since there is an increase in ON-current, the thinner the film thickness of the gate insulating film the greater the increase in the amount of charge in the inversion layer.

In addition, gate electrodes of such MOS transistors microstructured as described above are generally configured from impurity-doped polysilicon. Doping with substantial amounts of an impurity allows silicon, which is a semiconductor, to electrically function as a metal. However, in actuality, since silicon is polycrystalline, the impurity does not pass through the crystal grains or to the interface and the like of the gate insulating film and the polysilicon, so that the portions where the impurity does not permeate do not act as metal, but as a semiconductor.

In order to prevent such inhomogeneous distribution of an impurity, it is necessary to dope the polysilicon, which is a gate electrode, with large amounts of the impurity. In the MOS transistor fabrication process, in order to simplify the process, doping the gate electrode with an impurity is carried out simultaneous to formation of the source/drain diffusion layer, which is carried out after processing the gate electrode. Nevertheless, in order to form an integrated circuit including a microscopic MOS transistor, there is a necessity to make the source/drain diffusing-layer shallow, which conflicts with sufficient doping of an impurity within the gate electrode. An MOS transistor fabrication method is thus proposed, wherein a process for doping impurities, namely a pre-doping process, is provided after forming a polysilicon film, which becomes the material of a gate electrode, and before patterning this polysilicon film into a gate electrode.

FIGS. 5A through 5C and FIGS. 6A through 6C are cross-sectional views illustrating, in process order, a conventional MOS transistor fabrication method including a pre-doping process. In the drawings, an exemplary n-type MOS transistor fabrication method is illustrated, however, the fabrication method of a p-type MOS transistor is nearly the same.

To begin with, as shown in FIG. 5A, element isolation films 2 made from an oxide film are formed on the surface layer of a semiconductor substrate 1 using a shallow trench isolation method. Next, a channel layer 3 is formed on the semiconductor substrate 1 by doping the portion between the element isolation films 2 with an impurity. At this time, the type and amount of the to-be-doped impurity is adjusted so as to allow the designed threshold voltage to be obtained. For example, in the case of an nMOS transistor, after boron ions are implanted under the conditions where the acceleration energy is −300 keV and the implant dose is 1×10¹³ cm⁻², they are implanted under conditions where the acceleration energy is −30 keV and the implant dose is 7×10¹² cm⁻².

Next, as shown in FIG. 5B, a gate insulating film 4 is formed upon the channel layer 3. The gate insulating film 4 is comprised of a silicon oxide film comprising nitrogen, wherein the nitrogen content ratio is made to be, by mass, 2 to 5%. The gate insulating film 4 is formed using a rapid thermal oxidation (RTO) process carried out by a lamp annealer. Specifically, by applying heat of 850 to 1000° C. to an atmosphere of NO gas or mixed gas of oxygen and NO for 10 to 60 seconds and oxynitriding the surface layer of the channel layer 3, a 2 nm-thick silicon oxynitride film is formed as the gate insulating film 4.

Next, as shown in FIG. 5C, a polysilicon film 5, which is a gate electrode, is formed upon the element isolation films 2 and the insulating film 4 by a chemical vapor deposition (CVD) process. The deposition temperature of the polysilicon film 5 is set at about 620 to 650° C., and film thickness is set between 150 to 200 nm.

Next, as shown in FIG. 6A, a resist (not shown in the Figure) is formed, and using this resist as a mask, only the nMOS region is doped by implanting phosphorus ions under the conditions where the acceleration energy is −10 keV and the implant dose is 4×10¹⁵ cm⁻². Accordingly, pre-doping is carried out on the polysilicon film 5.

Next, as shown in FIG. 6B, a photoresist 6 is formed above the portion of the polysilicon film 5 whereon a gate electrode is to be formed. Then, using the photoresist 6 as a mask, high-selectivity etching is performed on the polysilicon film 5 and gate insulating film 4, patterning a gate electrode 11.

Next, as shown in FIG. 6C, SD-extensions 7a and 7b along with pockets (not shown in the Figure) for retaining short channel characteristics are formed by ion implantation, and rapid thermal annealing (RTA) is carried out at a temperature of approximately 1000° C. to repair the defects of the SD-extensions 7a and 7b, and sidewalls 8 are formed at a temperature between 700 and 800° C. Moreover, a source 9 and a drain 10 are formed by carrying out ion implantation concurrently with doping the gate electrode 11 with an impurity. Then, a silicide layer (not shown in the Figure) is formed; contact holes (not shown in the Figure) are formed; and by forming interconnects (not shown in the Figure) an n-type MOS transistor 12 is brought to completion.

In the n-type MOS transistor 12 formed by the aforementioned method, as shown in FIG. 6C, a semiconductor substrate 1 is provided; element isolation films 2 are provided at a fixed interval on the surface layer of the semiconductor substrate 1; and a channel layer 3 is provided sandwiched between the element isolation films 2. Furthermore, a source 9 and a drain 10 are provided so as to mutually face each other with space therebetween on the channel layer 3, and SD-extensions 7a and 7b are respectively provided at the portion of the source 9 facing the drain 10 and the portion of the drain 10 facing the source 9. In addition, a gate insulating film 4 is provided between the source 9 and the drain 10 as well as upon the SD-extensions 7a and 7b, and a gate electrode 11, which is made from polysilicon, is provided upon the gate insulating film 4. The side portions of the gate electrode 11 are covered by sidewalls 8.

However, the conventional techniques described above have the following problems. The polysilicon film, which becomes the material of the gate electrode, is not comprised solely of crystal grains, although it is called a polysilicon film. Even though there are many portions of crystals within the film, amorphous phases and crystallites exist around the crystal grains. Patterning of the gate electrode is carried out by dry etching of a highly selective ratio of silicon or a silicon oxynitride film; however, when there are existing amorphous phases in the polysilicon film, fluctuation in gate electrode formation increases since the etching speed differs in between the crystal portions and amorphous portions. As a result, there is the problem of increasing variations in the MOS transistor characteristics.

Furthermore, the diameters of the crystal grains in the polysilicon film configuring the gate electrode, are small immediately after deposition; however, there is crystal grain growth in a heat treatment step after deposition of the polysilicon film. In the heat treatment process after deposition of the polysilicon film 5, there is a heat treatment step carried out at 800 to 1000° C. for repairing defects of the SD-extensions 7a and 7b, which is carried out after implanting ions; and a thermal CVD step carried out at 700 to 800° C. for depositing a film to form the sidewalls 8, which are made of oxidized film, along with an activation heat treatment step carried out at 900 to 1100° C. during formation of the source 9 and drain 10. Since the heat treatments in these steps are carried out at a higher temperature than the deposition temperature of the polysilicon film 5, crystal growth progresses therein. The heat treatment step contributing the most to the increase in size and coarseness of crystal grains in the polysilicon film 5 out of the aforementioned heat treatment steps is the thermal CVD step during deposition of the sidewalls 8. When the aforementioned polysilicon film 5 comprising amorphous phases is heated at the deposition temperature, or a temperature of approximately 620 to 650° C. or more, the crystal grains existing before the application of heat absorb the surrounding amorphous phases and grow, increasing in size and coarseness. This phenomenon becomes particularly apparent by doping the polysilicon film with an impurity through the pre-doping process, which allows for the progression of crystal growth by the heat treatment at lower temperatures and shorter durations.

In this manner, such harmful effects, as described in the following, arise when crystal grains enlarge as crystal grain growth progresses in the polysilicon film. To begin with, most of the impurity doped into the gate electrode diffuses along the boundary of the crystal grains; however, as the crystal grains grow larger the number of grain boundary decreases. As a result, for example, when the vicinity of the polysilicon film surface is doped with an impurity using ion implantation and the like so as to cause diffusion through to the interface of the gate insulating film therewith, it becomes difficult for the impurity to reach this interface. Accordingly, when there is a lack of impurity near the interface of the gate electrode and gate insulating film, the portion near this interface becomes depleted, and the film thickness of the gate insulating film becomes substantially thicker. As a result, the effect of making the gate insulating film thinner is lost, and MOS transistor performance deteriorates.

Furthermore, as mentioned above, the impurity concentration throughout the polysilicon is not homogeneous, wherein it is high near the grain boundary configuring the diffusion path for the impurity, and low in the center thereof. If the respective diameters of the polysilicon crystal grains configuring the gate electrode are large, then since inhomogeneity of the impurity concentration within the gate electrode increases, variations in the electrical characteristics of the gate electrode increase.

In this manner, the pre-doping process is conventionally provided in order to prevent the depletion of the gate electrode; however, there is a problem where the increase in size and coarseness of the crystal grains in the gate electrode is facilitated by this pre-doping process, reducing the effect of preventing the depletion therein. Furthermore, since crystal portions and amorphous portions coexist within the polysilicon film that becomes the material of the gate electrode, there are problems of increasing variation in gate electrode form and MOS transistor characteristics.

### BRIEF SUMMARY OF THE INVENTION

### OBFECTS OF THE INVENTION

The object of the present invention is to provide a fabrication method of a high-performance MOS transistor with stable characteristics by preventing depletion of a gate electrode by making the distribution of impurity concentration homogeneous throughout the gate electrode as well as suppressing variation in gate electrode form.

### SUMMARY OF THE INVENTION

The MOS transistor fabrication method of the present invention comprises a step of forming a gate insulating film upon a semiconductor substrate; a step of forming a silicon film made from polysilicon or amorphous silicon upon the gate insulating film; a step of applying a heat treatment carried out at 800 to 1000° C. and for a duration of 1 to 10 seconds on the silicon film; a step of pre-doping by implanting impurity ions into the silicon film; a step of patterning a gate electrode by etching the silicon film; a step of forming sidewalls at the side portions of the gate electrode; and a step of doping the gate electrode with an impurity by implanting ions into the gate electrode and the semiconductor substrate as well as forming a source and a drain on the surface of the semiconductor substrate.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIG. 1 (A through D) is cross-sectional views illustrating, in process order, a MOS transistor fabrication method according to a first embodiment of the present invention;

FIG. 2 (A through C) is cross-sectional views illustrating steps subsequent to FIG. 1 of the MOS transistor fabrication method according to the this embodiment;

FIG. 3 (A through C) is cross-sectional views illustrating, in process order, a MOS transistor fabrication method according to a second embodiment of the present invention;

FIG. 4 is a graph illustrating variations in gate size of a comparative example and the embodiments of the present invention;

FIG. 5 (A through C) is cross-sectional views illustrating, in process order, a conventional MOS transistor fabrication method; and

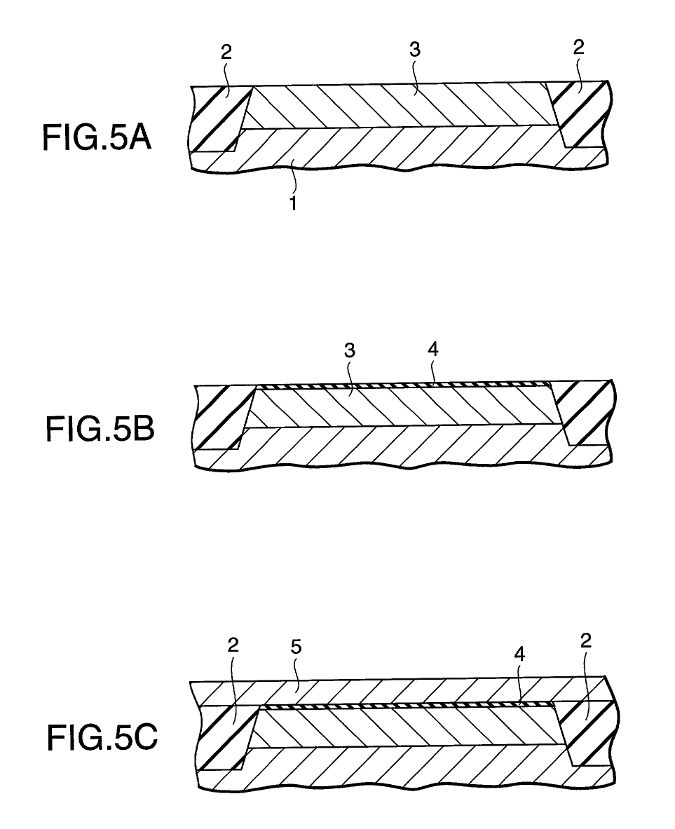

FIG. 6 (A through C) is cross-sectional views illustrating steps subsequent to FIG. 5 of a conventional MOS transistor fabrication method.

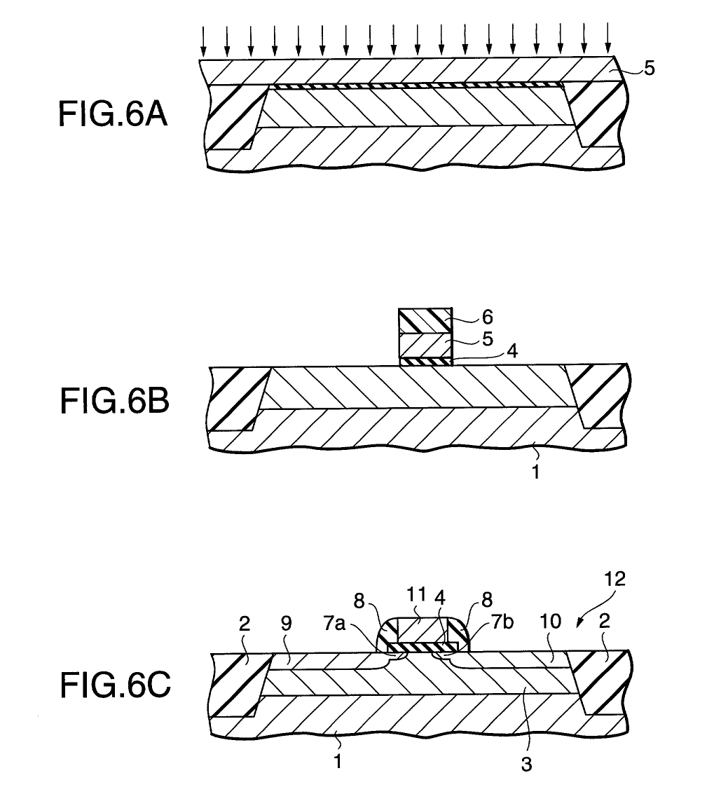

### DETAILED DESCRIPTION OF THE INVENTION

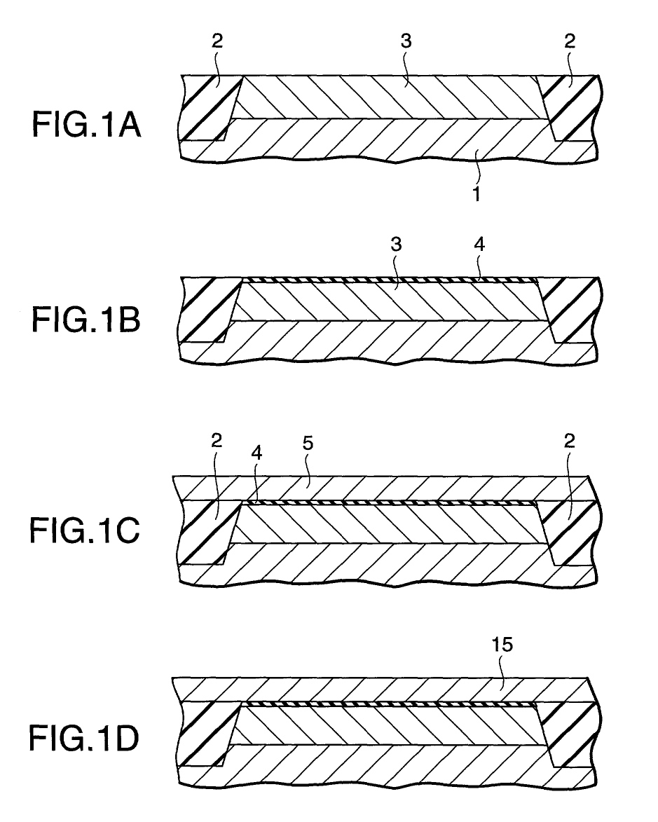

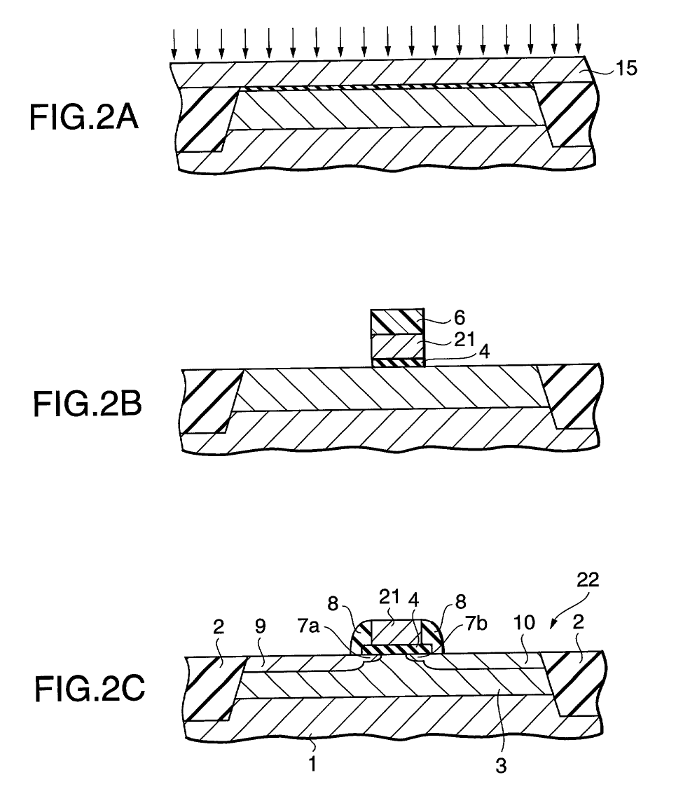

The embodiments of the present invention will be described in detail while referencing the attached drawings in the following. To begin with, FIGS. 1A through 1D and FIGS. 2A through 2C are cross-sectional views illustrating, in process order, a MOS transistor fabrication method of an embodiment of the invention. In this embodiment, an n-type MOS transistor fabrication method including a pre-doping process will be described.

To begin with, as shown in FIG. 1A, element isolation films 2 made from oxide film are formed a specified distance apart on the surface layer of a semiconductor substrate 1 by a shallow trench isolation method. Next, a channel layer 3 is formed by doping the portion between the element isolation films 2 on the semiconductor substrate 1 with an impurity. At this time, the type and amount of the to-be-doped impurity is controlled to obtain the designed threshold voltage. For example, in the case of an nMOS transistor, after boron ions are implanted under conditions where the acceleration energy is −300 keV and the implant dose is 1×10¹³ cm⁻², the channel layer 3 is formed by implanting ions under conditions where the acceleration energy is −30 keV and the implant dose is 7×10¹² cm⁻².

Next, as shown in FIG. 1B, a gate insulating film 4 is formed upon the channel layer 3. The gate insulating film 4 is configured from a silicon oxide film having, by mass, 2 to 5% nitrogen. Formation of the gate insulating film 4 is carried out through RTO by a lamp annealer. That is to say, by applying heat of 850 to 1000° C. to an atmosphere of NO gas, or mixed gas of oxygen and NO, for 10 to 60 seconds and oxynitriding the surface layer of the channel layer 3, a 2 nm-thick silicon oxynitride film is formed to give the gate insulating film 4.

Next, as shown in FIG. 1C, a polysilicon film 5, which becomes the gate electrode, is formed upon the element isolation films 2 and the insulating film 4 using a CVD process. The deposition temperature of the polysilicon film 5 is set at about 620 to 650° C., and film thickness is set between 150 and 200 nm.

Next, as shown in FIG. 1D, an RTA process is applied to the entire substrate by heating with a halogen lamp. Conditions for the heat treatment are set as: temperature of 800 to 1000° C.; a nitrogen atmosphere or a nitrogen atmosphere, which includes, by volume, about 0.01 to 1% added oxygen; and a duration of 1 to 10 seconds. As a result, the amorphous phases within the polysilicon film 5 crystallize, transforming into a stabilized polysilicon film 15 thereof.

Next, as shown in FIG. 2A, a resist (not shown in the Figure) is formed, and using this resist as a mask, only the nMOS transistor region is doped by implanting phosphorus ions under conditions where the acceleration energy is −10 keV and the implant dose is 4×10¹⁵ cm⁻². Accordingly, pre-doping is carried out on the polysilicon film 15.

Next, as shown in FIG. 2B, a photoresist 6 is formed above the portion of the polysilicon film 15 whereon a gate electrode is to be formed. Then, using the photoresist 6 as a mask, highly selective etching is performed on the polysilicon film 15 and gate insulating film 4, patterning a gate electrode 21.

Next, as shown in FIG. 2C, SD-extensions 7a and 7b along with pockets (not shown in the Figure) for retaining short channel characteristics are formed using the ion implantation method. At this time, part of the SD-extensions 7a and 7b diffuse below the gate insulating film 4. Furthermore, the impurity concentration of the SD-extensions 7a and 7b is higher than that of a conventional lightly-doped drain (LDD) region, and is a lower concentration than that of the source and drain formed in subsequent steps. Then, RTA is carried out at a temperature of 800 to 1000° C. so as to repair the defects of the SD-extensions 7a and 7b, and sidewalls 8 are formed at a temperature of 700 to 800° C. using a thermal CVD process. In addition, ion implantation is carried out, and a source 9 and drain 10 are formed by carrying out an activation heat treatment at a temperature of 900 to 1100° C. as well as implanting an impurity in the gate electrode 21. At this time, part of the source 9 and drain 10 diffuse below the sidewalls 8. Then, a silicide layer (not shown in the Figure) is formed; contact holes (not shown in the Figure) are formed; and by forming interconnects (not shown in the Figure), an n-type MOS transistor 22 is brought to completion.

Next, the configuration of the n-type MOS transistor 22 will be described. As shown in FIG. 2C, in the n-type MOS transistor 22, a semiconductor substrate 1 is provided; element isolation films 2 are provided at a fixed interval on the surface layer of the semiconductor substrate 1; and a channel layer 3 is provided sandwiched therebetween. Furthermore, a source 9 and a drain 10 are provided so as to mutually face each other with space therebetween on the channel layer 3, and SD-extensions 7a and 7b are respectively provided at the portion of the source 9 facing the drain 10 and the portion of the drain 10 facing the source 9. In addition, a gate insulating film 4 is provided between the source 9 and the drain 10 as well as upon the SD-extensions 7a and 7b, and a gate electrode 21, which is made from polysilicon, is provided upon the gate insulating film 4. Sidewalls 8 are provided at the side portions of the gate electrode 21.

In this embodiment, in the heat treatment process after deposition of the polysilicon film 5, there is a heat treatment step carried out at 800 to 1000° C. for repairing defects, which is carried out after implanting ions into the SD-extensions 7a and 7b ; and a thermal CVD step carried out at 700 to 800° C. for depositing a film to form the sidewalls 8 that are made from oxidized film, along with an activation heat treatment step carried out at 900 to 1100° C. when forming the source 9 and drain 10. The heat treatment step contributing the most to the increase in size and coarseness of the crystal grains in the polysilicon film 5 out of the aforementioned heat treatment steps is the thermal CVD step during deposition of the sidewalls 8. Increase in size and coarseness of crystal grains is facilitated through doping with an impurity, allowing for crystal grains in the pre-doped polysilicon to grow even greater in size.

In this embodiment, by applying the RTA process at a temperature of 800 to 1000° C. before the thermal CVD step of depositing a film at 700 to 800° C. in order to form the sidewalls 8, which are made from oxidized film, crystal growth is initiated in the amorphous phases in the polysilicon film 5 with the respective nuclei of the crystals existing at a constant ratio within the amorphous phases acting as a starting point. This causes the amorphous phases and crystallites within the film to grow into stable crystal grains. At this time, the crystal grains already existing before heating also grow; however, both grow at approximately the same speed, wherein effectually, the grain structure of the polysilicon film is stabilized by consuming the amorphous phases and crystallites concurrently while increasing the ratio of small crystals.

Even if the heat treatment used for deposition of the sidewalls 8 is applied to this stabilized polysilicon film 15, since amorphous phases do not exist, crystal grain growth is suppressed, and thus an increase in size and coarseness of the crystal grains may be prevented. Furthermore, since there are no amorphous phases existing in the polysilicon film 15, unevenness in etching speed does not occur when etching, thus fluctuation in gate electrode form may be prevented.

In this manner, by applying the RTA process after the polysilicon film is deposited, even through the pre-doping process for remedying gate electrode depletion and the heat treatment steps after this pre-doping process, a crystal structure with hardly any change in grain diameter in the gate electrode can be realized, as can the impurity concentration in the gate electrode be made homogeneous. As a result, a gate electrode with a homogeneous form is provided where depletion does not occur near the interface with the gate insulating film, allowing for the fabrication of a MOS transistor with little variation in characteristics.

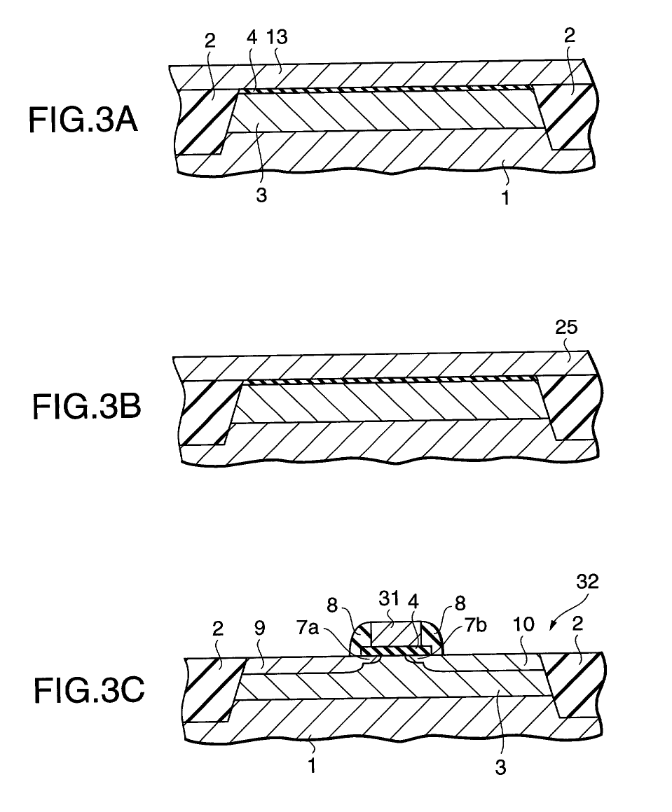

Next, a second embodiment of the present invention will be described. FIGS. 3A through 3C are cross-sectional views illustrating, in process order, a MOS transistor fabrication method according to the present embodiment of the invention. In this embodiment, an n-type MOS transistor fabrication method including a pre-doping process will be described. This embodiment differs from the aforementioned first embodiment in that an amorphous silicon film is used as material for the gate electrode.

To begin with, using the same methods as shown in FIGS. 1A and 1B, element isolation films 2, a channel layer 3, and a gate insulating film 4 are formed on a semiconductor substrate 1.

Next, as shown in FIG. 3A, an amorphous silicon film 13, which becomes a gate electrode, is formed upon element isolation films 2 and the gate insulating film 4 using a CVD process. The deposition temperature of the amorphous silicon film 13 is set at about 500 to 550° C., and film thickness is set between 150 and 200 nm.

Next, as shown in FIG. 3B, a heat treatment using RTA is applied to the entire substrate. Conditions for the heat treatment are set as: temperature of 800 to 1000° C.; a nitrogen atmosphere or a nitrogen atmosphere, which includes, by volume, about 0.01 to 1% added oxygen; and duration of 1 to 10 seconds. As a result, crystallization of the amorphous silicon film 13 is facilitated and crystal structure is stabilized, forming a stabilized polysilicon film 25.

Next, the same methods as shown in FIGS. 2A through 2C, an n-type MOS transistor 32 is formed.

Next, the configuration of the n-type MOS transistor 32 will be described. As shown in FIG. 3C, in the n-type MOS transistor 32, a semiconductor substrate 1 is provided; element isolation films 2 are provided at a fixed interval on the surface layer of the semiconductor substrate 1; and a channel layer 3 is provided sandwiched between the element isolation films 2. Furthermore, a source 9 and a drain 10 are provided so as to mutually face each other with space therebetween on the channel layer 3, and SD-extensions 7a and 7b are respectively provided at the portion of the source 9 facing the drain 10 and the portion of the drain 10 facing the source 9. In addition, a gate insulating film 4 is provided between the source 9 and the drain 10 as well as upon the SD-extensions 7a and 7b, and a gate electrode 21, which is made from polysilicon, is provided upon the gate insulating film 4. Sidewalls 8 are provided at the side portions of the gate electrode 31.

In this embodiment, since an amorphous silicon film 13 is deposited as material for the gate electrode 31, compared to the case where a polysilicon film 5 is deposited as shown in the aforementioned first embodiment, the temperature when depositing a film for the amorphous silicon 13 by CVD may be lowered. As a result, diffusion of the impurity in the channel layer 3 when depositing a film may be suppressed. Furthermore, by utilizing the amorphous silicon film 13 as material for the gate electrode 31, the crystal grain diameter after the RTA process may be further reduced. Accordingly, the diffusing speed of the doped impurity is further increased, and a more homogeneous concentration distribution thereof may be achieved.

It is noted that examples of fabricating an n-type MOS transistor have been illustrated in the first and second embodiments described above, however, with the present invention, a p-type MOS transistor may also be fabricated. The fabrication method of the p-type MOS transistor is also fundamentally the same as that of the n-type MOS transistor, differing only in the type of impurity ions used for implantation. With respect to depositing a polysilicon film or an amorphous silicon film upon the gate insulating film and carrying out the heat treatment under the aforementioned conditions before the pre-doping process, the p-type MOS transistor fabrication method is similar to that of the n-type transistor.

In the following, a comparative example differing from the fabrication method of the present invention and compared to the embodiments of the present invention will be concretely described. To begin with, the fabrication methods of n-type MOS transistors and p-type MOS transistors, which are the comparative example and the embodiments of the present invention, will be described. In the embodiments and the comparative example, four 8-inch wafers are prepared, and a plurality of the n-type MOS transistor and p-type MOS transistor of the embodiments, along with an n-type MOS transistor and p-type MOS transistor of the comparative example were formed on each wafer, respectively.

First of all, element isolation films made from oxide film were formed on the surface layer of the wafers. Next, a channel layer was formed by doping the portion between these element isolation films with an impurity. Subsequently, a gate insulating film was formed upon this channel layer. Then, a polysilicon film was formed upon the element isolation films and gate insulating film using a CVD process.

Afterwards, a heat treatment by RTA was applied to the n-type MOS transistor and p-type MOS transistor of the embodiments. At this time, the atmosphere was made to be a nitrogen atmosphere, the heating temperature to be 1000° C., and the heating time 1 second. The heat treatment by RTA was not carried out for the n-type and p-type MOS transistors of the comparative example.

Next, pre-doping was carried out on the aforementioned polysilicon film, and etching was performed on the polysilicon film and gate insulating film so as to fabricate into a gate electrode form therewith. At this time, the designed gate size of the gate electrode was set as 90 nm. Subsequently, SD-extensions and pockets were formed by ion implantation, sidewalls were formed by thermal CVD at a temperature of 700 to 800° C., and RTA was carried out at a temperature of 800 to 1000° C. so as to repair defects in the SD-extensions. Moreover, ion implantation was carried out, and an activation heat treatment was carried out at a temperature between 900 to 1100° C., to form a source and drain as well as dope the gate electrode with an impurity.

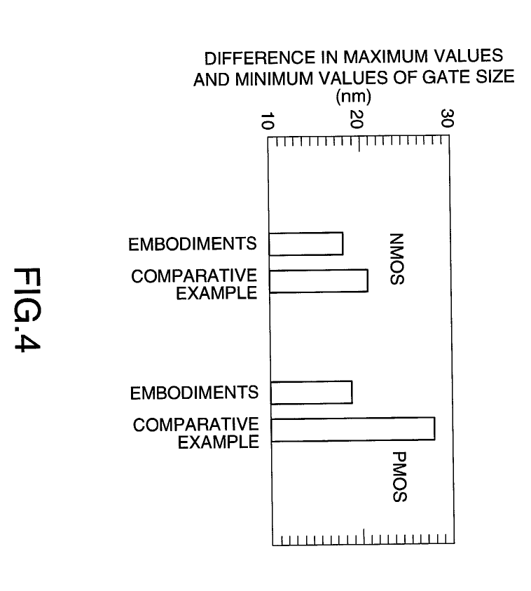

The fluctuation in gate size of the formed MOS transistor was measured as such. The gate size of the gate electrodes formed in 56 places within each 8-inch wafer were measured, looking for the difference between the maximum and minimum values. FIG. 4 is a graph illustrating the fluctuation in gate size of a comparative example and the embodiments of the present invention. The vertical axis of FIG. 4 indicates the aforementioned gate size difference. It shows that the smaller this value is, the fewer the variations within the wafer surfaces, and therefore the closer to being homogeneous.

With the n-type MOS transistor, variation in gate size on the wafers of the embodiments whereupon RTA processing was applied was decreased by approximately 10% in comparison to the wafers of the comparative example whereupon RTA processing was not applied. Moreover, with the pMOS transistor, variation in gate size on the wafers of the embodiments whereupon RTA processing was applied was decreased by approximately 30% in comparison to the wafers of the comparative example whereupon RTA processing was not applied. This is because on the wafers of the embodiments whereupon RTA processing was applied, since hardly any amorphous phases existed in the polysilicon film to therefore allow the etching speed to become even, variation in gate size decreased. On the other hand, on the wafers of the comparative example whereupon RTA processing was not applied, since amorphous phases did exist in the polysilicon films, differences in etching speed developed between the crystal portions and amorphous phases in the polysilicon film, and variation in gate size was great.

Basis for the numerical values of each structural component of the invention are hereupon described.

Heat treatment temperature: 800 to 1000° C.

With a heat treatment carried out at less than 800° C., crystallization of the amorphous phases in the silicon film is insufficient. On the other hand, when the temperature for the heat treatment exceeds 1000° C., diffusion of the impurity occurs in the channel layer, and characteristics of the channel layer such as the threshold voltage deviate from the designed value thereof. Moreover, the element separating characteristics deviate from the designed value thereof. Accordingly, the temperature for the heat treatment is set between 800 and 1000° C. It is noted that it is preferable that the RTA process be used as this heat treatment so as to suppress impurity diffusion in the channel layer during rising and falling temperatures, as well as suppress growth of the crystal grains existing in the silicon film before the heat treatment.

Heat treatment time: 1 to 10 seconds

With a heat treatment of less than 1 second, feedback control becomes difficult since the process time is too short, and evenness in temperature within the silicon film cannot be obtained. On the other hand, when the heat treatment temperature exceeds 10 seconds, diffusion of the impurity into the channel layer occurs since the semiconductor substrate becomes exposed to a high temperature atmosphere for a long period of time, wherewith channel layer characteristics such as threshold voltage deviate from the designed value thereof, as well as element separating characteristics deviating from the designed value thereof. Accordingly, the heat treatment time is set to be between 1 and 10 seconds.

According to the present invention as described in detail above, even in an MOS transistor fabrication method in which a pre-doping process is provided, by performing an RTA process after deposition of a polycrystalline or amorphous silicon film, which becomes material for the gate electrode, amorphous phases in the silicon film are allowed to be consumed and the crystal grains kept small. As a result, distribution of impurity concentration in the gate electrode is made homogeneous, depletion of the gate electrode is prevented and variation in the gate electrode form is controlled allowing for fabrication of a high-performance MOS transistor with stable characteristics.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A MOS transistor fabrication method comprising:
a step of forming a gate insulating film upon a semiconductor substrate; a step of forming a silicon film made from polysilicon or amorphous silicon upon said gate insulating film; a step of applying a heat treatment carried out at 800 to 1000° C. and for a duration of 1 to 10 seconds on said silicon film; a step of pre-doping by implanting impurity ions into said silicon film; a step of patterning a gate electrode by etching said silicon film; a step of forming sidewalls at the side portions of said gate electrode; and a step of doping said gate electrode with an impurity by implanting ions into said gate electrode and said semiconductor substrate as well as forming a source and a drain on the surface of said semiconductor substrate.

2. The MOS transistor fabrication method mentioned in claim 1, wherein said heat treatment is an RTA process carried out in a nitrogen atmosphere or a nitrogen atmosphere having, by volume, less than 1% oxygen.

3. The MOS transistor fabrication method mentioned in claim 1, wherein said heat treatment is an RTA process using a halogen lamp.

4. The MOS transistor fabrication method mentioned in claim 1, wherein said gate electrode is formed from a silicon oxynitride substance less than 2 nm-thick.

5. The MOS transistor fabrication method mentioned in claim 1, wherein said silicon film is formed using a chemical vapor deposition method.

6. The MOS transistor fabrication method mentioned in claim 1 comprising a step of forming an element isolation region on the surface of said semiconductor substrate before said step of forming a gate electrode upon a semiconductor substrate.
